(19) United States
(12) Patent Application Publication
(10) Pub. No.: US 2009/0124061 A1
(43) Pub. Date: May 14, 2009

(54) METHOD FOR MANUFACTURING SEMICONDUCTOR DEVICE

(76) Inventor: Masahiro KIYOTOSHI, Yokkaichi-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/253,765

(22) Filed: Oct. 17, 2008

(30) Foreign Application Priority Data
Oct. 19, 2007 (JP) 2007-272501

(51) Int. Cl. H01L 21/762

(52) U.S. Cl. 438/435; 257/E21.546

(57) ABSTRACT

A method for manufacturing a semiconductor device, comprises forming an isolation trench on a semiconductor substrate, exposing a silicon surface of the isolation trench formed on the semiconductor substrate, filling a first insulating film into the semiconductor substrate by means of TEOS/O₃/H₂O CVD, filling a second insulating film into the isolation trench, and processing the first and second insulating films so that the second insulating film remains into the portion of the isolation trench.

### CROSS-REFERENCE TO RELATED APPLICATION

This application is based upon and claims the benefit of priority from the prior Japanese Patent Application No. 2007-272501, filed on Oct. 19, 2007; the entire contents of which are incorporated herein by reference.

### BACKGROUND OF THE INVENTION

1. Field of the Invention

The invention relates to a method for manufacturing a semiconductor device. The invention particularly relates to a method for manufacturing a semiconductor device having an STI (Shallow Trench Isolation).

2. Related Art

In order to improve performance (enhanced operating speed and reduced power consumption) of elemental devices due to higher integration and to reduce the manufacturing cost, shrink of LSI (Large Scale Integrated circuits) is advanced. In recent years, mass-production of flash memories whose minimum design rule is less than 50 nm has started. It is predicted that further scale-down of the flash memory will be continued though technical difficulty will be severer. Since an element isolation region occupies over a half of a device area, it is important for rapid shrinkage of the device that scale-down of the element isolation region is executed as the scale-down of the active area.

In recent years, as a method for forming an element isolation region suitable for the above-mentioned shrinkage of the device, the STI for filling an insulating film into a trench formed by anisotropic etching is used. A width of the isolation trench has reduced less than 50 nm.

However, due to such shrinkage of the STI, difficulty in steps of filling the insulating film into the isolation trenches rapidly increases. This is because the isolation between adjacent elements is determined by an effective distance between the adjacent elements, namely, the shortest distance making a detour from the isolation region. However, in order to shrink the device and avoid deterioration of an insulating property, the effective distance should be maintained, namely, a trench depth of the STI should be equal everywhere in the whole STI even in case of the further shrunk device. Further, as the trench width of the STI becomes thinner due to the shrinkage of LSI, an aspect ratio of the trench into which the insulating film is filled becomes larger, and thus difficulty to fill the insulating film into the STI is rapidly increasing. As a result, the number of process steps of forming the STI of highly shrunk semiconductor device steadily increases (Japanese Patent Publication Laid-Open No. 2004-311487).

### BRIEF SUMMARY OF THE INVENTION

According to an aspect of the present invention, there is provided a method for manufacturing a semiconductor device, comprising:

forming an isolation trench on a semiconductor substrate;

exposing a silicon surface of the isolation trench formed on the semiconductor substrate;

filling a first insulating film into the semiconductor substrate by means of TEOS/O₃/H₂O CVD;

filling a second insulating film into the isolation trench; and

processing the first and second insulating films so that the second insulating film remains into the portion of the isolation trench.

### BRIEF DESCRIPTION OF THE DRAWINGS

FIGS. 1 to 6 are cross-sectional views illustrating steps of a method for manufacturing a semiconductor device according to the first embodiment of the present invention.

FIGS. 7 to 12 are cross-sectional views illustrating steps of the semiconductor device manufacturing method according to the second embodiment of the present invention.

FIG. 13 is cross-sectional views illustrating steps of a alternative method for manufacturing a semiconductor device according to the first embodiment of the present invention.

### DETAILED DESCRIPTION OF THE INVENTION

Embodiments of the present invention are described below with reference to the drawings. The following embodiments are only examples of the present invention, and they do not limit the scope of the present invention.

### First Embodiment

A first embodiment of the present invention is described. In the first embodiment of the present invention, the STI of a floating gate type flash memory is filled up using a silicon oxide film formed by TEOS/O₃/H₂O CVD (Chemical Vapor Deposition using TEOS/O₃/H₂O) as a first insulating film and a SOD (Spin on Dielectric) film as a second insulating film.

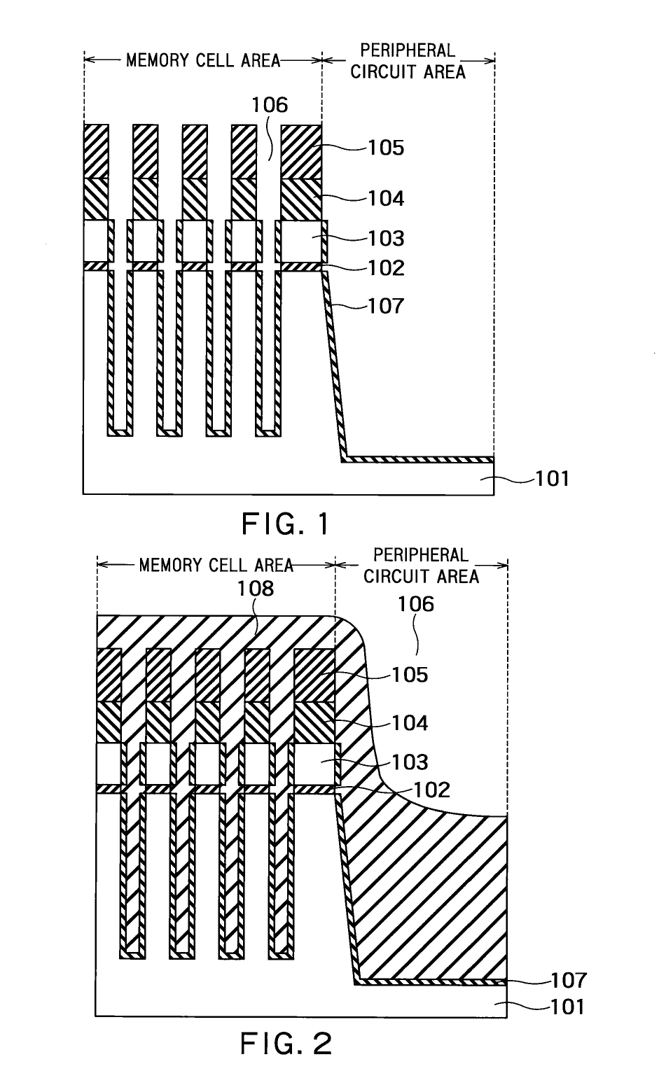

FIGS. 1 to 5 are cross-sectional views illustrating steps of a method for manufacturing a semiconductor device according to the first embodiment of the present invention.

The steps of forming a structure in FIG. 1 are described first.

A silicon thermal oxynitride film 102 (8 nm) to be a gate insulating film, a P-doped polycrystalline silicon film 103 (60 nm) to be a floating gate, a silicon nitride film 104 (60 nm) to be a polishing stopper for CMP (Chemical Mechanical Polishing), and a CVD silicon oxide film 105 (200 nm) to be a mask for RIE (Reactive Ion Etching) are stacked on a semiconductor substrate (for example, silicon substrate) 101. A photoresist film (not shown) is further applied on the stacked materials.

The photoresist film is processed by a lithography technique, and the CVD silicon oxide film 105 is processed by RIE in which the photoresist film is used as a mask, so that a hard mask is formed. At this time, a width of the isolation trench 106 of the memory cell area is 30 nm.

The photoresist is removed using an asher and by a wet etching using a sulfuric acid/hydrogen peroxide mixture solution.

The silicon nitride film 104, the P-doped polycrystalline silicon film 103, the silicon thermal oxynitride film 102, and the semiconductor substrate 101 are sequentially processed by RIE in which the processed CVD silicon oxide film 105 is used as a hard mask. As a result, a trench with a depth of 220 nm is formed.

A reactive product at the RIE step is removed by executing a diluted fluoric acid treatments and the isolation trench 106 of a memory cell area and a peripheral circuit area to be the STI is formed. At this time, a chemical oxide 107 (1 nm) is formed on the inner surface of the isolation trench 106 at a cleaning step in HCl/H₂O₂ solution or HCl/O₃ aqueous solution. It is preferable for bottom-up type filling at a step of filling the first insulating film, which will be mentioned later, to make the silicon exposed on the inner surface of the isolation trench 106. However, the chemical oxide 107 of about 1 nm thickness is allowed. With the above steps, the structure shown in FIG. 1 is completed. In the first embodiment of the present invention, the forming the chemical oxide 107 is selectable, and is preferable. A controllability of forming films can be improved by forming the chemical oxide 107.

Steps of forming a structure in FIG. 2 are described below.

In the structure of FIG. 1, a silicon oxide film 108 to be the first insulating film is formed on the stacked materials by TEOS/O₃/H₂O CVD. In the TEOS/O₃/H₂O CVD, film deposition temperature is 400 to 500° C. and deposition pressure is 400 to 600 Torr. A deposited film thickness of the silicon oxide film 108 is 220 nm. With the above steps, the structure in FIG. 2 is completed.

In case of the TEOS/O₃/H₂O CVD, silicon oxide film is selectively grown from the surface of the silicon substrate in the isolation trench 106 and its deposition advances into a favorable bottom-up shape. Therefore, the memory cell area is completely filled with the silicon oxide film 108 to the upper portion of the silicon nitride film 104 under the above deposition conditions. Further, the isolation trench 106 having a large trench area of the peripheral circuit area is almost filled up and a thick silicon oxide film 108 of more than 100 nm is formed on the side walls of the isolation trench 106 of the peripheral circuit area. The thick silicon oxide film 108 formed on the side walls of the isolation trench 106 of the peripheral circuit area suppress the peeling of an SOD film 109, mentioned later, at the time of thermal densification, and yield of the semiconductor device can be improved. Moreover, process turnaround time of TEOS/O₃/H₂O CVD can be much shortened in comparison with the case of filling all isolation trenches with TEOS/O₃/H₂O CVD only, since TEOS/O₃/H₂O CVD deposition speed is slow.

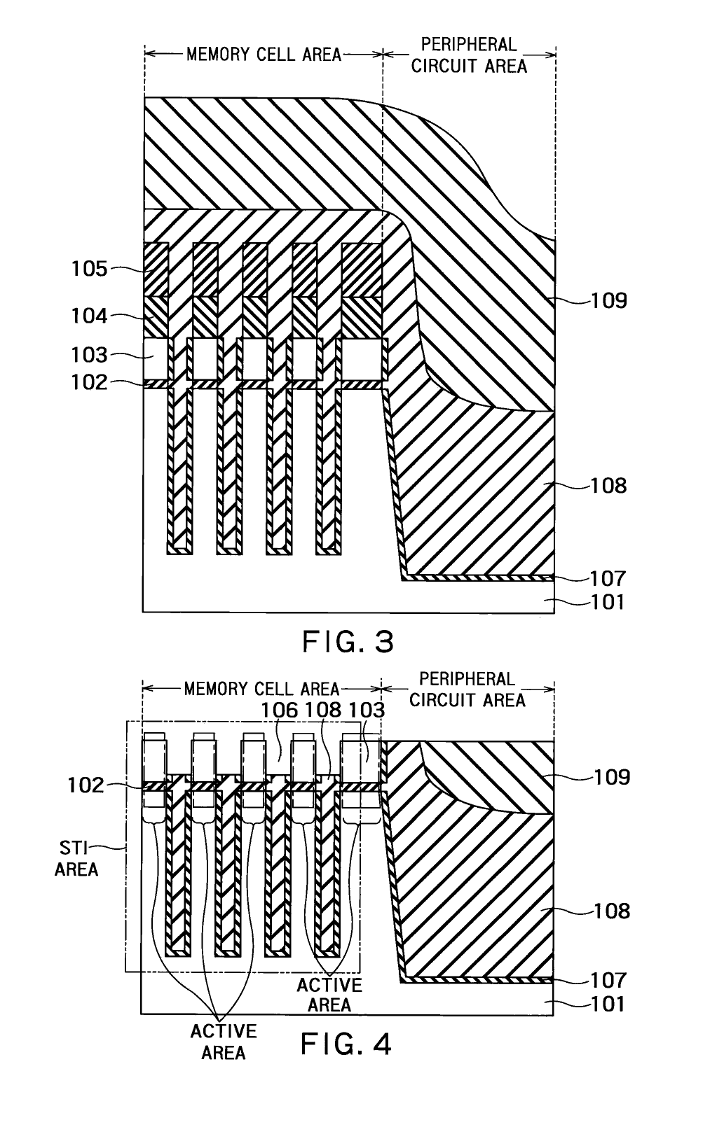

Steps of forming a structure in FIG. 3 are described below.

In the structure of FIG. 2, the SOD film 109 (for example, poly-silazane film) to be the second insulating film is formed on an upper portion of the isolation trench 106 which is half-filled with the silicon oxide film 108. Since the SOD film 109 has a fluidity, it is filled without seam and void into also a portion, where the silicon oxide film 108 has an overhang shape due to the shape of the isolation trench 106 or incomplete selectivity on the semiconductor substrate 101.

The deposition for forming the SOD film 109 using the poly-silazane film is described.

Perhydro-silazane polymer [(SiH₂NH)ₙ], whose mean molecular weight is 2000 to 6000, is dissolved into xylene, dibutyl ether or the like, so that perhydro-silazane polymer solution is produced.

The perhydro-silazane polymer solution is subjected to the surface of the semiconductor substrate 101 by a spin coating method. For example, as to conditions of the spin coating method, a rotating speed of the semiconductor substrate 101 is 1000 rpm, rotating time is 30 seconds, a subjected amount of the perhydro-silazane polymer solution is 2 cc, and an expected film thickness is 250 nm just after baking.

Since the isolation trench 106 having the large trench area of the peripheral circuit area is already raised to more than 200 nm by the silicon oxide film 108, a thickness of the SOD film 109 can be thinner than the case of filling all isolation trench 106 with SOD film 109 only. Therefore, a crystalline defect due to stress of the SOD film 109 can be suppressed. Also, transistor threshold voltage deviation caused by fixed charges at the interface of the semiconductor substrate 101 and the SOD film 109 can be suppressed, which are generated by impurities (C, N) due to the SOD film 109, since the impurities diffuse to the semiconductor substrate 101 and reacts with the semiconductor substrate 101 to form positive fixed charges.

The SOD film 109 formed on the silicon oxide film 108 is heated to 150° C. on a hot plate for three minutes in an inert gas atmosphere. As a result, a solvent in the perhydro-silazane polymer solution is volatilized so that a poly-silazane film is formed. At this time, a several percent to a dozen percent of carbon or carbon hydride due to the solvent remain as impurities in the poly-silazane film. The poly-silazane film is close to a silicon nitride film which contains residual solvent and has low film density.

The poly-silazane film is oxidized in a low pressure steam atmosphere at 400° C. under a condition that an oxidizing amount of the semiconductor substrate 101 is 0.6 nm, so that oxygen is substituted for the nitrogen in the poly-silazane film. As the result, the poly-silazane film is converted to a silicon oxide film.

The SOD film 109 is processed by CMP. With the above steps, the SOD film 109 of the poly-silazane film is formed.

Since the impurities (C, N and the like) in the SOD film 109 hardly diffuses into the silicon oxide film 108 at the low temperature as 400° C., fixed charges due to the SOD film 109 are not generated.

Steps of forming a structure in FIG. 4 are described below.

In the structure of FIG. 3, in order to remain the silicon oxide film 108 only inside the isolation trench 106, the SOD film 109, the silicon oxide film 108 and the CVD silicon oxide film 105 are polished by CMP using the silicon nitride film 104 as a stopper.

The SOD film 109 is densified by annealing in a nitrogen atmosphere for 30 minutes at the temperature of 850° C. In general, in the case of such a high-temperature heat treatment, impurities (C, N) in the SOD film 109 easily diffuse, and fixed charges are easily generated at the interface of the semiconductor substrate 101. However, in the first embodiment of the present invention, since insulating films in the isolation trench 106 of the peripheral circuit area is formed up to the upper surface of the P-doped polycrystalline silicon film 103 due to the silicon oxide film 108, a remaining volume of the SOD film 109 after CMP becomes sufficiently small. Therefore, fixed charges can be generated as low as possible.

Table 1 shows an off leak current I_{off} of a high-voltage circuit section of a peripheral circuit in the case of applying a general heat treatment (the heat treatment given before CMP) and the case of the first embodiment of the present invention (the heat treatment given after CMP).

As shown in Table 1, in the first embodiment of the present invention, since a width (W) of an active area easily influenced by the fixed charges of isolation trench 106 is narrow, the off leak current (I_{off}) is reduced by one or more digit.

TABLE 1

| | | Heat Treatment According |
|---|---|---|
| | General Heat | to First Embodiment of |
| | Treatment | the Present Invention |
| HV Tr I_{off} (W = 10 um) | 1.2E⁻¹⁰ [A/um] | 8.9E⁻¹¹ [A/um] |
| HV Tr I_{off} (W = 2 um) | 1.3E⁻⁹ [A/um] | 9.5E⁻¹¹ [A/um] |

In the case of the general heat treatment, an SOD film 109 occasionally peels due to a stress caused by large volume shrinkage of the SOD film 109. However, in the first embodiment of the present invention, since the silicon oxide film 108 having the more than 100 nm thickness is formed on the side walls of the isolation trench 106 of the peripheral circuit area, it is completely suppressed that the SOD film 109 peels.

In the first embodiment of the present invention, since oxidation of the floating gate caused by steam oxidation can be sufficiently reduced by the silicon oxide film 108 to be diffusion barrier, bird's beak oxidation during curing of SOD film 109 is also suppressed.

In the first embodiment of the present invention, improved annealing, for example a higher-temperature steam annealing, can be employed.

The silicon oxide film 108 which remains in the isolation trench 106 of the memory cell area is etched back by 50 nm with RIE.

Only the silicon oxide film 108 which remains in the isolation trench 106 of the memory cell area is further etched back by 40 nm with the conventional lithography technique and RIE.

The silicon nitride film 104 is removed in hot phosphoric acid, so that an STI area is formed. At the above steps, the structure of FIG. 4 is completed.

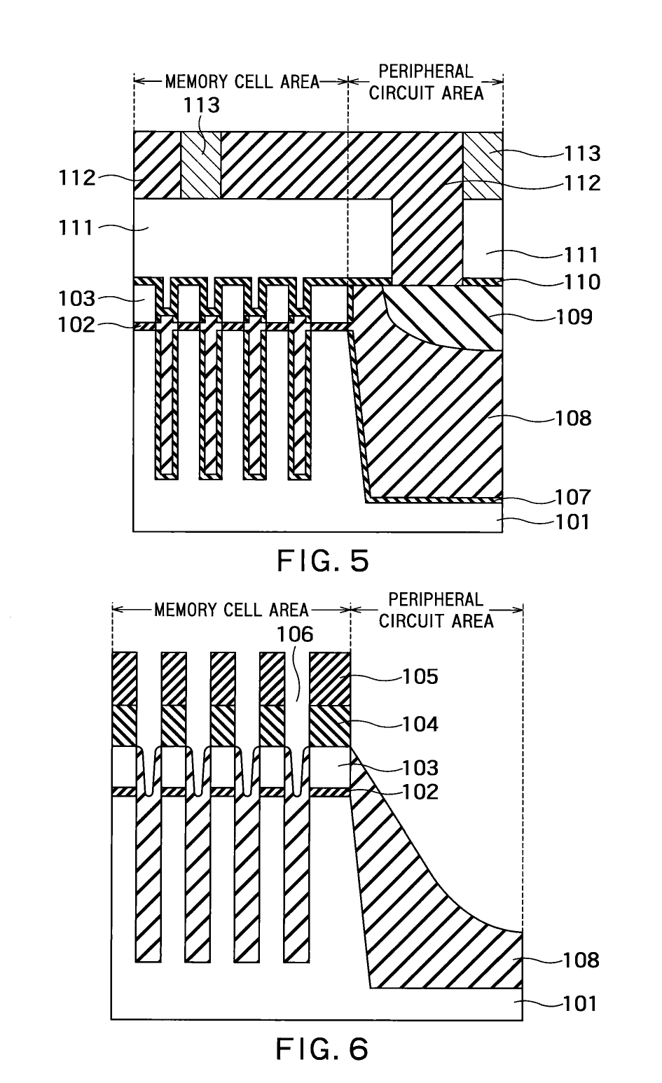

The steps of forming a structure in FIG. 5 are described below.

In the structure of FIG. 4, an ONO film 110 to be an IPD (inter-poly-silicon gate dielectric film) is formed on the P-doped polycrystalline silicon film 103, the silicon oxide film 108, and the SOD film 109. In general, in a pre-treatment process in which the ONO film 110 is deposited, a hydrofluoric acid treatment is necessary for removing a native oxide film on the surface of the P-doped polycrystalline silicon film 103 to be the floating gate. However, in the first embodiment of the present invention, the isolation trench 106 of the memory cell area is filled with only the silicon oxide film 108 formed by TEOS/O₃/H₂O CVD, in which the silicon oxide film 108 grows into a bottom-up shape without seam and void, and it is suppressed that the wet-etching-resistance of the SOD film 109 is poor. Therefore, divot or void of the isolation trench 106 of the memory cell area caused by local erosion with wet etching is prevented.

The P-doped polycrystalline silicon film 111 to be a control gate electrode is formed on the ONO film 110.

The P-doped polycrystalline silicon film 111 and the ONO film 110 are sequentially processed by the lithography technique and RIE. As a result, the control gate and the floating gate are formed.

An ILD (inter-layer dielectric film) 112 is formed on the SOD film 109 and the P-doped polycrystalline silicon film 111. A contact plug 113 is formed on the P-doped polycrystalline silicon film 111. The other wires layer and the like (not shown) are formed on the stacked structure. With the above steps, the structure in FIG. 5 is completed.

In the first embodiment of the present invention, the gap-fill shape of the silicon oxide film 108 to be the first insulating film may be a concaved shape such that the lower portion of the isolation trench 106 of the memory cell area is mainly filled up as shown in FIG. 6 instead of the shape shown in FIG. 2 such that the isolation trench 106 of the memory cell area is completed filled up. In this case, the isolation trench 106 of the memory cell area is filled with two kinds of insulating films. However, when the structure in FIG. 6 is employed, the wet etching rate of the SOD film 109 at the center of the isolation trench 106 of the memory cell area is much higher than the silicon oxide film 108 at the sidewalls of the isolation trench 106 of the memory cell area. Therefore, the final shape of the isolation trench 106 of the memory cell area becomes concaved shape. When the structure in FIG. 6 is employed, parasitic capacitance between adjacent floating gates in the control gate projecting portion at the center of the isolation trench 106 of the memory cell area is effectively reduced.

The first embodiment of the present invention describes the example that the poly-silazane film is formed as the SOD film 109, but an HSQ (hydrogen silses-quioxane) film, a poly-silazane or the like may be formed as the SOD film 109.

The first embodiment of the present invention describes the example of the device structure of the floating gate type flash memory, but the present invention may be applied to a device structure of a MONOS type flash memory.

According to the first embodiment of the present invention, the isolation trench 106 of the memory cell area and a part of the isolation trench 106 of the peripheral circuit area are filled with the silicon oxide film 108 formed by TEOS/O₃/H₂O CVD whose gap-fill property is selective, and remaining isolation trenche 106 of the peripheral circuit area is filled with the SOD film 109. Therefore, a thickness of the silicon oxide film 108 by TEOS/O₃/H₂O CVD can be minimized. Furthermore, the processing time for forming the silicon oxide film 108 can be shortened. Furthermore, even when the lack of the silicon oxide film 108 is occurred due to improper condition of surface of the semiconductor substrate 101 or improper shape (for example, rough surface) of the isolation trench 106, the SOD film 109 will fill the lack of the silicon oxide film 108. Therefore, satisfactory performance of the isolation trench 106 can be obtained.

According to the first embodiment of the present invention, since the silicon oxide film 108 is completely filled into the isolation trench 106 of the memory cell area up to the silicon nitride film 104, the isolation trench 106 of the memory cell area has a single-layered structure. As a result, wet etching at a later stage can be easily carried out.

### Second Embodiment

A second embodiment of the present invention is described below. The first embodiment of the present invention describes the example that STI in the device having structure of the flash memory is filled up. However, the second embodiment of the present invention describes an example that STI in a logic device is filled up. The description about contents similar to those in the first embodiment of the present invention is not repeated.

In the conventional semiconductor manufacturing process, at a hybrid filling step of forming a HDP (High Density Plasma)-CVD silicon oxide film on an upper portion of STI, the first insulating film such as an O₃/TEOS film or a SOG (Spin on Glass) film is firstly filled into the isolation trench, then the isolation trench is once planarized by CMP. Thereafter, the filled insulating film is etched back to a desired depth by RIE and wet etching, then the HDP-CVD silicon oxide film is filled as the second insulating film.

However, since the CMP and etching back steps for the first insulating film are necessary for this process flow, the number of the manufacturing process step for the semiconductor device increases and process flow becomes more complicated. Furthermore, it is difficult to reduce a thickness of the silicon nitride film as the CMP stopper for controlling the etch-back of the first insulating film and carry out CMP 2 times, namely, fill STI.

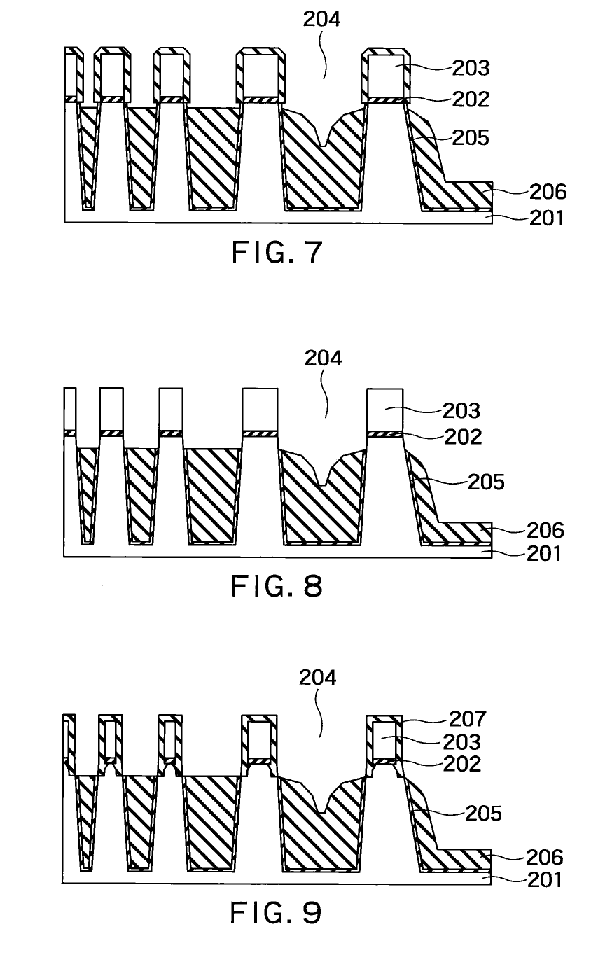

FIGS. 7 to 12 are cross-sectional views illustrating steps of the semiconductor device manufacturing method according to the second embodiment of the present invention.

Steps of forming a structure in FIG. 7 are described first.

A silicon thermal oxide film 202 (4 nm) to be a sacrificial oxide film, a silicon nitride film 203 (100 nm) to be a polishing stopper of CMP, and a CVD silicon oxide film to be a mask of RIE are stacked on a semiconductor substrate (for example, a silicon substrate) 201. A photoresist film (not shown) is further applied on the stacked materials.

The photoresist film is processed by the conventional lithography technique, and the CVD silicon oxide film is processed by RIE where the photoresist film is used as a mask. As a result, a hard mask is formed.

The photoresist film is removed using an asher and by etching using a sulfuric acid/hydrogen peroxide mixture solution.

The silicon nitride film 203, the silicon thermal oxide film 202 and the semiconductor substrate 201 are sequentially processed by RIE where the processed CVD silicon oxide film is used as the hard mask. As a result, a trench with depth of 250 nm is formed.

The CVD silicon oxide film and a reactive product at the RIE step are removed by a DHF (Diluted Hydrofluoric Acid) wet etching process, so that an isolation trench 204 to be STI is formed. At this time, chemical oxide 205 (1 nm) is formed on an inner surface of the isolation trench 204 at a cleaning step in a HCl/H₂O₂ aqueous solution or a HCl/O₃ aqueous solution. In order to carry out bottom-up gap-fill at a gap-fill step at a later stage, it is important that the silicon is exposed on the inner surface of the isolation trench 205. However, a chemical oxide 205 of about 1 nm is allowed.

A silicon oxide film 206 (120 nm) to be the first insulating film is formed in the isolation trench 204 by TEOS/O₃/H₂O CVD. A deposition temperature of TEOS/O₃/H₂O CVD is 450 to 500° C., and a deposition pressure is 400 to 600 Torr. Under these conditions, the silicon oxide film 206 is deposited into about 10 nm in a conformal manner, and grows into a bottom-up shape selectively from the surface of the isolation trench 204, and raised by about 240 nm on a narrow area whose width is less than 100 nm. With the above steps, the structure in FIG. 7 is completed.

Steps of forming structure in FIG. 8 are described below.

In the structure of FIG. 7, DHF wet etching is carried out so that the silicon oxide film 206 is removed by 10 nm, and the conformal deposited film formed at the beginning of the deposition of the silicon oxide film 206 is removed. This step is a step which is executed at a step of filling an HDP-CVD silicon oxide film 208, mentioned later, in order to prevent remaining of the silicon oxide film 206 only on the side wall of the isolation trench 204. With these steps, the structure in FIG. 8 is completed.

Steps of forming a structure in FIG. 9 are described below.

In the structure of FIG. 8, the semiconductor substrate 201 and the silicon nitride film 203 are oxidized by 5 nm by an ISSG (In-Situ Steam Generation) oxidizing technique which supplies hydrogen and oxygen at a high temperature so as to generate H₂O radical as an oxidizing agent. The silicon thermal oxide film 207 is, then, formed. As a result, the silicon nitride film 203 is recessed with respect to the side surface of an active area, and the end portion of the active area is rounded by oxidation. With these steps, the structure in FIG. 9 is completed.

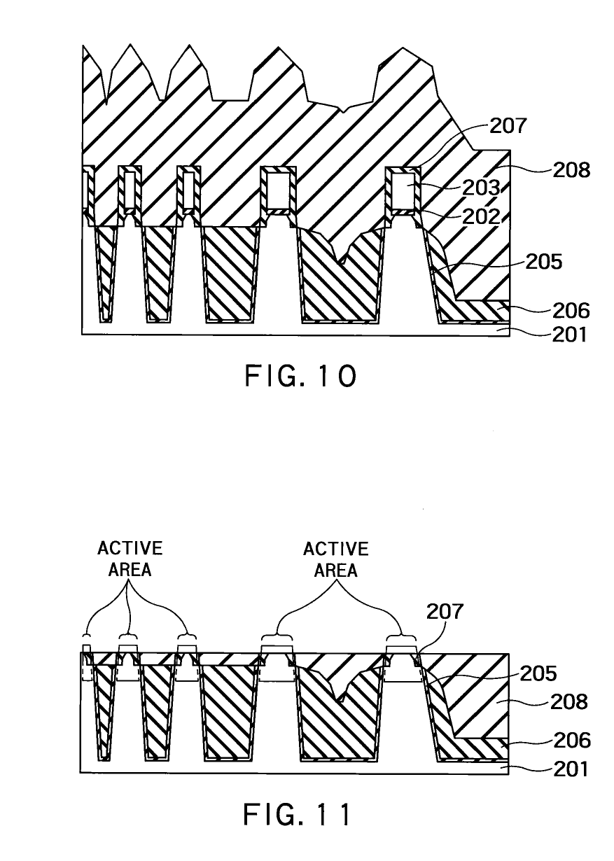

Steps of forming a structure in FIG. 10 are described below.

In the structure of FIG. 9, the HDP-CVD silicon oxide film 208 to be the second insulating film is deposited over the entire surface of the stacked materials. Although gap-fill performance of the HDP-CVD silicon oxide film 208 strongly depends on the shape of the isolation trench 204, since the bottom of the narrow isolation trench 204 is raised by filling the silicon oxide film 206 into the isolation trench 204, the HDP-CVD silicon oxide film 208 can be filled without void relatively easily. With the above steps, the structure in FIG. 10 is completed.

Steps of forming a structure in FIG. 11 are described below.

In the structure of FIG. 10, the HDP-CVD silicon oxide film 208 and the silicon oxide film 206 are polished by CMP where the silicon nitride film 203 is used as a stopper so as to remain the HDP-CVD silicon oxide film 208 and the silicon oxide film 206 only inside the isolation trench 204.

The height of the isolation trench 204 is adjusted by wet etch-back using buffered hydrofluoric acid.

The silicon nitride film 203 is removed in hot phosphoric acid, and the silicon thermal oxide film 202 is removed by wet etching with hydrofluoric acid. At this time, since the silicon nitride film 203 is recessed with respect to the side surface of the active area due to ISSG oxidation, divots at the edge of the isolation trench 204 can be suppressed. With these steps, the structure in FIG. 11 is completed.

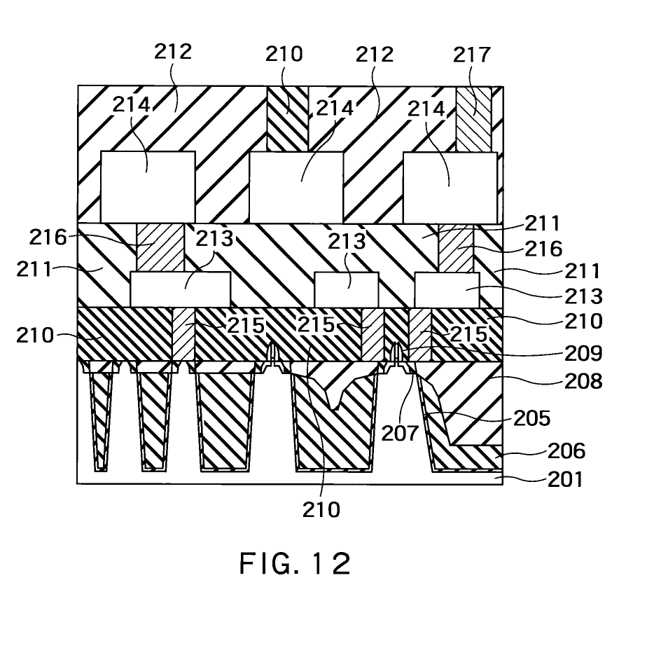

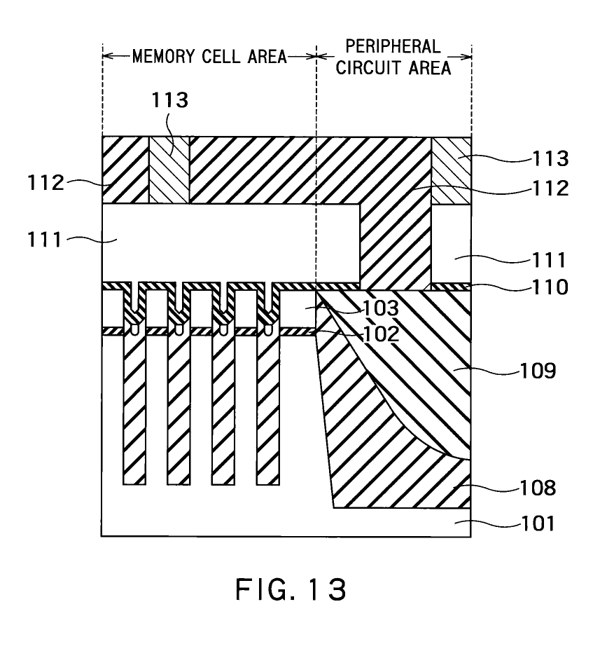

Steps of forming a structure in FIG. 12 are described below.

In the structure of FIG. 11, a gate insulating film, a gate electrode, a side wall spacer and a diffusion layer are formed on the stacked materials so that a transistor 209 is formed.

A PMD/ILD film (pre-metal dielectric film or an inter-layer dielectric film) 210 to 212, wires 213 and 214, and contact plugs 215 to 217 are formed on the stacked materials. With these steps, the structure in FIG. 12 is completed.

In the second embodiment of the present invention, the STI forming method may be applied not only to a logic device but also to any devices (for example, DRAM, SRAM, PRAM, NOR flash, NAND flash, MONOS memory devices) as long as they are formed with a gate oxide film and a gate electrode after STI is formed.

According to the second embodiment of the present invention, since the silicon oxide film 206 is formed by using the TEOS/O₃/H₂O CVD, the approximately uniform bottom-up shaped silicon oxide film 206 can be formed in the isolation trench 204 with width of not more than 100 nm. The hybrid fill of the silicon oxide film 206 and the HDP-CVD silicon oxide film 208 can be realized without the CMP and etch-back steps.

Further, according to the second embodiment of the present invention, since the HDP-CVD silicon oxide film 208 is filled into only the upper portion of the isolation trench 204, a high wet etching resistance can be realized for the wet etching step at a plurality times at the time of forming a plurality of gate oxide films. Further, the shrinkage of the STI can be realized as an integration degree is steadily increased.

What is claimed is:

1. A method for manufacturing a semiconductor device, comprising:
forming an isolation trench on a semiconductor substrate;
exposing a silicon surface of the isolation trench formed on the semiconductor substrate;
filling a first insulating film into the semiconductor substrate by means of TEOS/O₃/H₂O CVD;
filling a second insulating film into the isolation trench; and
processing the first and second insulating films so that the second insulating film remains into the portion of the isolation trench.

2. The method for manufacturing a semiconductor device according to claim 1, wherein at the forming the isolation trench, before the isolation trench is formed, in a memory cell area, a stacked film including a gate insulating film and a floating gate electrode film or a stacked film including a gate insulating film and a charge trap film is formed, and the stacked film is processed.

3. The method for manufacturing a semiconductor device according to claim 1, further comprising:
forming chemical oxide after the exposing the silicon surface.

4. The method for manufacturing a semiconductor device according to claim 1, further comprising:
oxidizing an active area after filling the first insulating film.

5. The method for manufacturing a semiconductor apparatus according to claim 1, wherein an SOD film is the second insulating film filled into the isolation trench of a peripheral circuit area.

6. The method for manufacturing a semiconductor device according to claim 2, further comprising:
forming chemical oxide after exposing the silicon surface.

7. The method for manufacturing a semiconductor device according to claim 2, further comprising:
oxidizing an active area after filling the first insulating film.

8. The method for manufacturing a semiconductor device according to claim 2, wherein an SOD film is the second insulating film of a peripheral circuit area.

9. The method for manufacturing a semiconductor device according to claim 3, further comprising:
oxidizing an active area after filling the first insulating film.

10. The method for manufacturing a semiconductor device according to claim 3, wherein an SOD film is the second insulating film of a peripheral circuit area.

11. The method for manufacturing a semiconductor device according to claim 4, wherein an SOD film is the second insulating film of a peripheral circuit area.

12. The method for manufacturing a semiconductor device according to claim 6, further comprising:
oxidizing an active area after filling the first insulating film.

13. The method for manufacturing a semiconductor device according to claim 6, wherein an SOD film is the second insulating film of a peripheral circuit area.

14. The method for manufacturing a semiconductor device according to claim 7, wherein an SOD film is the second insulating film of a peripheral circuit area.

15. The method for manufacturing a semiconductor device according to claim 1, wherein the first insulating film is filled so that the isolation trench of a memory cell area is completely filled up with the first insulating film.

16. The method for manufacturing a semiconductor device according to claim 1, wherein the first insulating film is filled so that the lower portion of the isolation trench of the memory cell area is partially filled up.

17. The method for manufacturing a semiconductor device according to claim 1, wherein the second insulating film is an HDP-CVD silicon oxide film.

18. The method for manufacturing a semiconductor device according to claim 2, wherein the first insulating film is filled so that the isolation trench of the memory cell area is completely filled up with the first insulating film.

19. The method for manufacturing a semiconductor device according to claim 2, wherein the first insulating film is filled so that the lower portion of the isolation trench of the memory cell area is partially filled up.

20. The method for manufacturing a semiconductor device according to claim 2, wherein the second insulating film is an HDP-CVD silicon oxide film.
